(19) United States
(12) Patent Application Publication
(10) Pub. No.: US 2004/0160616 A1
(43) Pub. Date: Aug. 19, 2004

(54) Black and white image color mark removal

(75) Inventors: Hanqiang Huang, Irvine, CA (US); Yung-Kai Lai, Irvine, CA (US)

Correspondence Address: CHARLES C.H. WU, 7700 IRVINE CENTER DRIVE, SUITE 710, IRVINE, CA, 92618-3043, US

(73) Assignee: MATCH LAB, INC.

(21) Appl. No.: 10/370,362

(22) Filed: Feb. 18, 2003

(51) Int. Cl. G06F 15/00; H04N 1/38; G03F 3/08

(52) U.S. Cl. 358/1.9; 358/461; 358/463; 358/518

(57) ABSTRACT

A method and apparatus for processing an input image to remove color marks from the input image. The method includes the steps of detecting RGB entries in a CMS table that are not on a gray diagonal proximity. Next, the method changes output space values for the RGB entries to a shade of gray. Finally, the method converts the input image to an output image by referencing the CMS table.

### BACKGROUND OF THE INVENTION

1. Field of the Invention

The invention relates in general to image processing. More particularly, this invention relates to a method for removing color marks in a black and white document to restore the original black and white document.

2. Description of the Related Art

In the processing of images, the removal of stray marks is desired. For example, color marks may be applied to a black and white image. The black and white original may be altered by colored pens, highlighted with markers, or stamped. It is often desired to remove the color marks, thus restoring the original black and white image.

In U.S. Pat. No. 5,850,298, Narahara discloses an image processing device forming a reproduced image from a plurality of color recording signals, each of which is generated at a corresponding one of scans on an original image and derived from color digital signals obtained at the corresponding one of the scans, includes a threshold value generation unit generating a threshold value based on the color digital signals at a first one of the scans, and a background removal unit reducing background noise in the reproduced image by using the threshold value at second and following ones of the scans. In summary, the image-processing device of Narahara uses the background removal unit to remove pixels below the threshold value. The subject invention, on the other hand, removes colored marks by modifying a color matching system table. The subject invention does not use a background removal unit or generate a threshold value based on color digital signals.

In U.S. Pat. No. 5,048,109, Bloomberg discloses a method and apparatus for detection of highlighted regions of a document. A document containing highlighted regions is scanned using a gray scale scanner. Morphology and threshold reduction techniques are used to separate highlighted and non-highlighted portions of the document. Having separated the highlighted and non-highlighted portions, optical character recognition (OCR) techniques can then be used to extract text from the highlighted regions. The method in Bloomberg performs morphology and threshold reduction techniques on a gray scale copy of the original image. The subject invention, on the other hand, detects color marks in the original image deviating from the RGB gray-scale diagonal (i.e. the straight line where Red=Green=Blue). Once detected, the method of the subject invention removes the color marks.

### SUMMARY OF THE INVENTION

Accordingly, one object of the present invention is to provide an image processing device and method that detect color marks in an image.

A second object of the invention is to provide an image processing device and method that remove color marks from an image.

To achieve these and other advantages and in accordance with the purpose of the invention, as embodied and broadly described herein, the invention provides a method and apparatus for processing an input image to remove color marks from the input image. The method includes the steps of detecting RGB entries in a CMS table that are not on a gray diagonal proximity. Next, the method changes output space values for the RGB entries to a shade of gray. Finally, the method converts the input image to an output image by referencing the CMS table.

Both the foregoing general description and the following detailed description are exemplary and explanatory only and are not restrictive of the invention, as claimed.

### BRIEF DESCRIPTION OF THE DRAWINGS

FIG. 1 is an overall block diagram illustrating the process of the present invention;

FIG. 2 is a block diagram that illustrates the process of updating the CMS table;

FIG. 3 illustrates an example of an updated CMS table;

FIG. 4 illustrates the gray diagonal in the RGB color space;

### DESCRIPTION OF THE PREFERRED EMBODIMENTS

Before proceeding with a description of the method and apparatus of the present invention, a summary of the RGB color space, which may be helpful in understanding the disclosed embodiment, is provided RGB color is composed of specified values of red, green, and blue components. A combination of these three colors create all of the other colors in a digital representation of an image.

In a 24-bit color system, the red, green, and blue components are each allotted 8 bits. This may be referred to as an “RGB color triplet.” Each color component within the RGB color triplet has a value in the range of 0 to 255. (R,G,B)=(0,0,0) represents black, an absence of color. (R,G,B)=(255,255,255), on the other hand, represents white. Any value where R=G=B is a shade of gray, and falls along the gray diagonal.

In the method of the present invention, removal of color marks is accomplished by modifying the Color Matching System (CMS) table, which converts input in RGB color space into a proper output color space. An often-used output space is Cyan-Magenta-Yellow (CMY) or Cyan-Magenta-Yellow-Black (CMYK) space, which is the common format for color printing.

CMYK color is specified by the cyan, magenta, yellow and black components in a color. Cyan is equivalent to “not red” or 255 red-intensity. Magenta may be thought of as “not green” or 255 green-intensity. Yellow is “not blue” or 255 blue-intensity.

This patent uses CMYK as an example, but other color spaces may also be used.

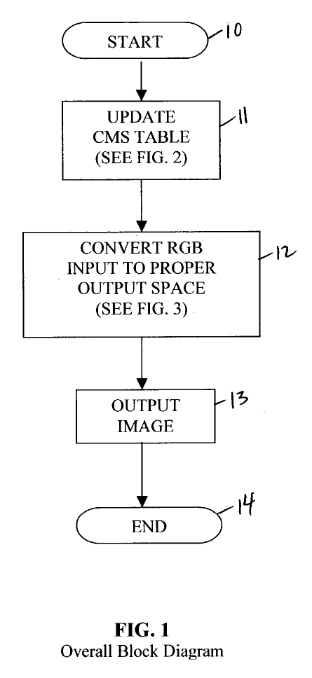

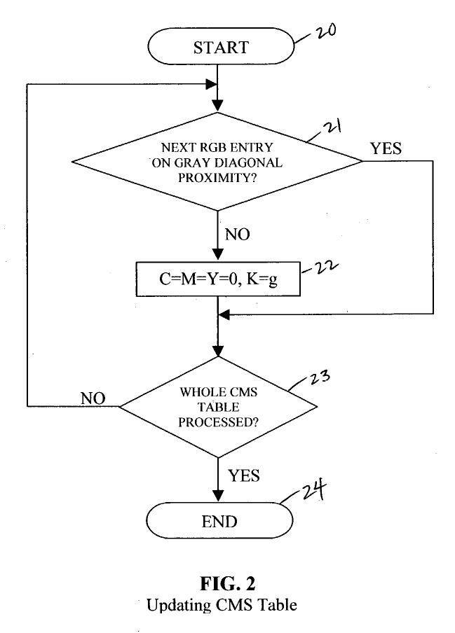

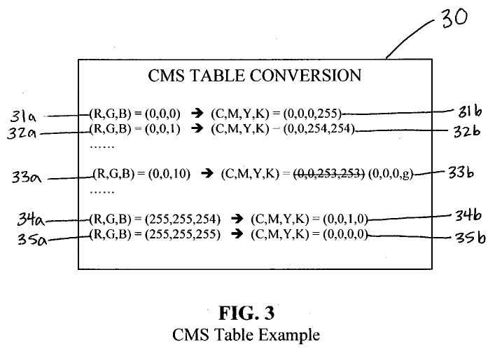

Referring now to FIG. 1, a block diagram of the overall process of the present invention is shown. The process begins with start bubble 10 followed by a process step of updating the CMS table (block 11). When updating the CMS table, the method of the present invention sets all RGB entries away from the gray diagonal to a gray diagonal background color. Modification of the CMS table is further described in FIG. 2. Once the table is modified, process step 12 converts the inputted RGB image into a proper output color space. In this example, the output space used is the CMYK space. As stated above, other output spaces may be used. FIG. 3 illustrates a sample conversion table from RGB input to CMYK output. After converting the image to the appropriate output space, a process step outputs the image (block 13). The process then exits (end bubble 14).

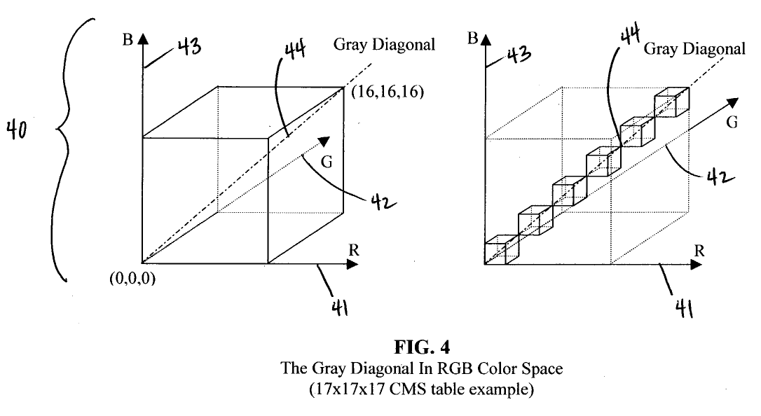

With reference to FIG. 2, a block diagram illustrates the process of updating the CMS table. The process begins with start bubble 20 followed by an inquiry as to whether the next RGB entry is on the gray diagonal proximity (decision diamond 21). The gray diagonal proximity represents all RGB color triplets directly on the gray diagonal, or within an allowed proximity of the gray diagonal. The gray diagonal proximity is further described in FIG. 4. If the answer to the inquiry posed by decision diamond 21 is no, the process modifies the CMYK values associated with the RGB entry. In modifying the CMYK values, the C, M and Y components are set to 0, and the black component (K) is set to the gray diagonal background color. Next, the process poses an inquiry as to whether the entire CMS table has been processed (decision diamond 23). If the answer to this inquiry is no, the process returns to decision diamond 21, and continues until all RGB entries within the CMS table are accounted for. The process then exits (end bubble 24).

Referring now to FIG. 3, an example of an updated CMS table 30 is shown. CMS table 30 contains RGB values like 31a, 32a, 33a, 34a and 35a. For each RGB value, CMS table 30 contains a corresponding CMYK value such as 31b, 32b, 33b, 34b and 35b. In practice, CMS table 30 may not provide entries for all possible input RGB values. In this case, some uniformly or non-uniformly spaced RGB lattice values and their transform to, CMYK space is provided, while other in-between RGB-to-CMYK transformation is obtained by interpolating from neighboring RGB-to-CMYK table entries.

With reference to FIG. 3, some of the CMYK entries have been modified because they are not on the gray diagonal proximity. For example, RGB entry 33a has a value of (0,0,10). Since this value is not on the gray diagonal proximity, the original CMYK value of (0,0,253,253) was updated by the method of the present invention to (C,M,Y,K)=(0,0,0,g).

With reference to FIG. 4, a diagram of the gray diagonal 44 in the RGB color space 40 is shown. This diagram corresponds to a 17×17×17 CMS table. The RGB color space 40 includes a red component 41, a green component 42, and a blue component 43. RGB color triplet (0,0,0) represents black, the absence of color. RGB color triplet (16, 16, 16), on the other hand, represents white. The diagonal line connecting the white and black corners represents the gray diagonal 44, i.e. the straight line where R=G=B. Between the gray diagonal 44 and the cube's surface, colors would grade from a gray shade to a pure color. The method of the present invention keeps the colors near the gray diagonal unchanged because they represent the original black-and-white image. Colors away from the gray diagonal are color marks, and are reset to a gray diagonal background color.

Referring to FIG. 4, all RGB cubes in a TxTxT CMS table on the gray diagonal 44 have the eight vertices (d,d,d), (d,d,d+1), (d,d+1,d), (d,d+1,d+1), (d+1,d,d), (d+1,d,d+1), (d+1,d+1,d), (d+1,d+1,d+1), where 0<=d<(T−1). The method of the present invention keeps the corresponding table entries unchanged. For all other entries, the process sets CMYK to the background color. For example, if the background color is white, the method of the present invention sets (C,M,Y,K)=(0,0,0,0). If the background color is a gray color, the process sets (C,M,Y,K)=(0, 0, 0, g). That is, for every RGB entry (R,G,B), the process sets (C,M,Y,K)=(0,0,0,g) if:

R<d or d+1<R

G<d or d+1<G where 0<=d<(T−1)

B<d or d+1<B

where g is the gray scale of the background color corresponding to (R,G,B) in the proximity of (d,d,d).

In practical cases, color deviation from the gray diagonal is inevitable. Some tolerance parameter DT may be inserted into the process. Every RGB entry in the proximity of the gray diagonal has a modified CMYK value. For every RGB entry (R,G,B), the process sets (Q,M,Y,K)=(0,0,0,g) if:

R<d−DT or d+1+DT<R

G<d−DT or d+1+DT<G where 0<=d<(T−1)

B<d−DT or d+1+DT<B

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A method for processing an input image to remove color marks from the input image, the method comprising the steps of:
detecting RGB entries in a CMS table that are not on a gray diagonal proximity;
changing output space values for the RGB entries to a shade of gray; and
converting the input image to an output image by referencing the CMS table.

2. The method according to claim 1 wherein the input image is in RGB format.

3. The method according to claim 1 wherein the output space is a CMYK output space.

4. The method according to claim 1 wherein the output space is a CMY output space.

5. The method according to claim 1 wherein the step of converting the input image includes matching an RGB entry in the CMS table with a portion of the input image.

6. The method according to claim 1 wherein the step of converting the input image includes interpolating adjacent RGB entries in the CMS table to match a portion of the input image.

7. The method according to claim 1 wherein the gray diagonal proximity includes colors directly on the gray diagonal.

8. The method according to claim 1 wherein the gray diagonal proximity includes colors within a tolerance parameter range of the gray diagonal.

9. The method according to claim 1 wherein the shade of gray is a background color of the input image.

10. The method according to claim 1 wherein the shade of gray ranges from black to white.

11. An image processing device forming a reproduced image without color marks, the image processing device comprising:
an input unit capable of receiving RGB input; and
a CMS table coupled to the input unit, wherein the CMS table is capable of referencing output space values for RGB input, and wherein the CMS table changes output space values for RGB entries not on a gray diagonal to a shade of gray.

13. The image processing device according to claim 11 wherein the output space is a CMYK output space.

14. The image processing device according to claim 11 wherein the output space is a CMY output space.

15. The image processing device according to claim 11 wherein the CMS table references output space values by matching an RGB entry in the CMS table with RGB input.

16. The image processing device according to claim 11 wherein the CMS table references output space values by interpolating adjacent RGB entries in the CMS table to match RGB input.

17. The image processing device according to claim 11 wherein the gray diagonal proximity includes colors directly on the gray diagonal.

18. The image processing device according to claim 11 wherein the gray diagonal proximity includes colors within a tolerance parameter range of the gray diagonal.

19. The method according to claim 11 wherein the shade of gray is a background color of the input image.

20. The method according to claim 1 wherein the shade of gray ranges from black to white.
